(19) United States
(12) Patent Application Publication
(10) Pub. No.: US 2007/0075417 A1
(43) Pub. Date: Apr. 5, 2007

(54) MEMS module package using sealing cap having heat releasing capability and manufacturing method thereof

(75) Inventors: Young-Nam Hwang, Suwon-si (KR); Yeong-Gyu Lee, Suwon-si (KR); Suk-Kee Hong, Seoul (KR); Heung-Woo Park, Seoul (KR)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: Samsung Electro-Mechanics Co., Ltd., Suwon-si (KR)

(21) Appl. No.: 11/543,391

(22) Filed: Oct. 4, 2006

(30) Foreign Application Priority Data
Aug. 7, 2006 (KR) 10-2006-0074338
Oct. 5, 2005 (KR) 10-2005-0093265

(51) Int. Cl. H01L 23/12

(52) U.S. Cl. 257/704

(57) ABSTRACT

A MEMS module package using a sealing cap having heat releasing capability is disclosed, which comprises a lower substrate, a MEMS element mounted on the lower substrate, a driver integrated circuit mounted on the lower substrate adjacently to the MEMS element which operates the MEMS element, and a sealing cap positioned in contact with the lower substrate which has a MEMS-element protrusion portion in physical contact with the MEMS element and has one or more grooves for housing the MEMS element and the driver integrated circuit. The MEMS module package using a sealing cap having heat releasing capability and a manufacturing method thereof according to an aspect of the present invention utilize an effective heat releasing structure to release the heat generated in each element.

### BACKGROUND

1. Technical Field

The present invention relates to a semiconductor package, and in particular, to a MEMS module package using a sealing cap having heat releasing capability and a manufacturing method thereof.

2. Description of the Related Art

MEMS (microelectromechanical systems) is a technology that uses semiconductor manufacturing technology to form three-dimensional structures on silicon substrates. There are a variety of applications in which MEMS is used, examples of which include various sensors for vehicles, inkjet printer heads, HDD magnetic heads, and portable telecommunication devices, in which the trend is towards smaller devices capable of more functionalities. The MEMS element has a movable part spaced from the substrate to perform mechanical movement. The description below will focus on the optical modulator, from among various MEMS structures. An optical modulator is a circuit or device which loads signals on a beam of light (optical modulation) when the transmission medium is optical fiber or free space in the optical frequency range. The optical modulator is used in such fields as optical memory, optical display, printers, optical interconnection, and holograms, etc., and a great deal of development research is currently under way on display devices using the optical modulator. The descriptions below will focus on the optical modulator element, from among various MEMS elements.

The optical modulator element can be divided mainly into a direct type, which directly controls the on/off state of light, and an indirect type, which uses reflection and diffraction, where the indirect type may further be divided into an electrostatic type and a piezoelectric type. Here, the optical modulator element includes a plurality of equally spaced-apart deformable reflective ribbons having reflective surface portions and suspended above the upper part of the substrate. Thus, the light reflected off the reflective surface portions and reflective ribbons is diffracted, to emit a light corresponding to a signal.

FIG. 1 is a cross-sectional view of a MEMS module package using a sealing cap according to prior art. Referring to FIG. 1, a MEMS module package is illustrated which includes a lower substrate 110, first adhesive 120(1), 120(2), a sealing cap 130, a MEMS element 140, driver IC's (driver integrated circuits) 150(1), 150(2), second adhesive 160(1), 160(2), a printed circuit board 170, and third adhesive 180.

The lower substrate 110 allows the transmission of incident light entering the MEMS element 140 and of reflected and diffracted light emitted from the MEMS element 140. The first adhesive 120(1), 120(2), second adhesive 160(1), 160(2), and third adhesive 180 attach the sealing cap 130 to the lower substrate 110, the MEMS element 140 to the driver IC's 150(1), 150(2) and the lower substrate 110, and the printed circuit board 170 to the sealing cap 130, respectively.

According to prior art, to reduce the defect rate during sealing operations for a micromirror array module, such as a MEMS element 140, and to improve the reliability and workability, the cap sealing method of using a sealing cap 130 is currently used. That is, by performing the sealing using a sealing cap 130, the penetration of humidity is reduced and the performance of the element is improved. However, as this produces a structure which seals the portion where heat is generated, problems may occur due to the difficulty in heat release. Such a difficulty can incur malfunctions both directly and indirectly, so that there is a need for a heat releasing structure to resolve this problem.

### SUMMARY

The present invention aims to provide a MEMS module package using a sealing cap having heat releasing capability and a manufacturing method thereof, which utilize an effective heat releasing structure to release the heat generated in each element.

Another object of the invention is to provide a MEMS module package using a sealing cap having heat releasing capability and a manufacturing method thereof, which utilize the sealing cap connected to each element to release the heat generated.

Yet another object of the invention is to provide a MEMS module package using a sealing cap having heat releasing capability and a manufacturing method thereof, in which a variety of heat releasing structures are joined to the sealing cap to effectively release the heat generated in the elements.

Still another object of the invention is to provide a MEMS module package using a sealing cap having heat releasing capability and a manufacturing method thereof, in which thermally conductive material is positioned between the sealing cap and each element so that the processing of the sealing cap is made convenient and the inner structure of the sealing cap can be adjusted freely as necessary.

Yet another object of the invention is to provide a MEMS module package using a sealing cap having heat releasing capability and a manufacturing method thereof, having a structure that allows the heat generated in each element to be released through the sealing cap and a heat release plate.

Other objectives of the present invention will be readily understood from the description set forth below.

One aspect of the invention may provide a MEMS module package using a sealing cap having heat releasing capability, comprising a lower substrate, a MEMS element mounted on the lower substrate, a driver integrated circuit mounted on the lower substrate adjacently to the MEMS element which operates the MEMS element, and a sealing cap positioned in contact with the lower substrate which has a MEMS-element protrusion portion in physical contact with the MEMS element and has at least one groove for housing the MEMS element and the driver integrated circuit.

The sealing cap according to embodiments of the invention may further comprise a driver-IC protrusion portion positioned in physical contact with the driver integrated circuit.

Another aspect of the invention may provide a MEMS module package using a sealing cap having heat releasing capability, comprising a lower substrate, a MEMS element mounted on the lower substrate, a driver integrated circuit mounted on the lower substrate adjacently to the MEMS element which operates the MEMS element, a sealing cap positioned in contact with the lower substrate which has at least one groove for housing the MEMS element and the driver integrated circuit, and a MEMS-element heat conductive material housed in the groove formed in the sealing cap which keeps the MEMS element and the sealing cap in physical contact.

The MEMS module package according to embodiments of the invention may further comprise a driver-IC heat conductive material housed in the groove and positioned in physical contact with the driver integrated circuit.

Here, the MEMS-element heat conductive material or the driver-IC heat conductive material may be heat conductive paste or heat conductive pads.

Embodiments of the invention may also include one or more of the following features.

The lower substrate may be formed from a transparent material.

Also, the MEMS module package according to embodiments of the invention may further comprise a printed circuit board positioned on the sealing cap which transfers electric signals to the driver integrated circuit.

Also, the MEMS module package according to embodiments of the invention may further comprise a printed circuit board positioned under the lower substrate which transfers electric signals to the driver integrated circuit.

In addition, the MEMS module package according to embodiments of the invention may further comprise a heat release plate housed in a hole formed in the printed circuit board which allows heat conduction from the sealing cap.

Also, the MEMS module package according to embodiments of the invention may further comprise a heat release plate positioned on the printed circuit board and configured to allow heat conduction from the sealing cap, where the heat release plate and the sealing cap may be connected by one or more heat paths formed in the printed circuit board.

The MEMS element may be an optical modulator which reflects and diffracts modulated light in correspondence to an operation signal received from the driver integrated circuit.

Additional aspects and advantages of the present invention will be set forth in part in the description which follows, and in part will be obvious from the description, or may be learned by practice of the invention.

### DESCRIPTION OF THE DRAWINGS

FIG. 1 is a cross-sectional view of a MEMS module package using a sealing cap according to prior art.

FIG. 2A is a perspective view of a diffraction type optical modulator module using piezoelectric elements, applicable to an embodiment of the invention.

FIG. 2B is a perspective view of another diffraction type optical modulator module using piezoelectric elements, applicable to an embodiment of the invention.

FIG. 2C is a plan view of a diffraction type optical modulator array applicable to an embodiment of the invention.

FIG. 2D is a schematic diagram illustrating an image generated on a screen by means of a diffraction type optical modulator array applicable to an embodiment of the invention.

FIG. 2E is a cross-sectional view of a MEMS module package using a sealing cap having heat releasing capability according to a first disclosed embodiment of the invention.

FIG. 3 is a cross-sectional view of a MEMS module package using a sealing cap having heat releasing capability according to a second disclosed embodiment of the invention.

FIG. 4 is a cross-sectional view of a MEMS module package using a sealing cap having heat releasing capability according to a third disclosed embodiment of the invention.

FIG. 5 is a cross-sectional view of a MEMS module package using a sealing cap having heat releasing capability according to a fourth disclosed embodiment of the invention.

FIG. 6 is a cross-sectional view of a MEMS module package using a sealing cap having heat releasing capability according to a fifth disclosed embodiment of the invention.

FIG. 7 is a cross-sectional view of a MEMS module package using a sealing cap having heat releasing capability according to a sixth disclosed embodiment of the invention.

FIGS. 8 to 10 are graphical representations of thermal conduction analysis according to embodiments of the invention.

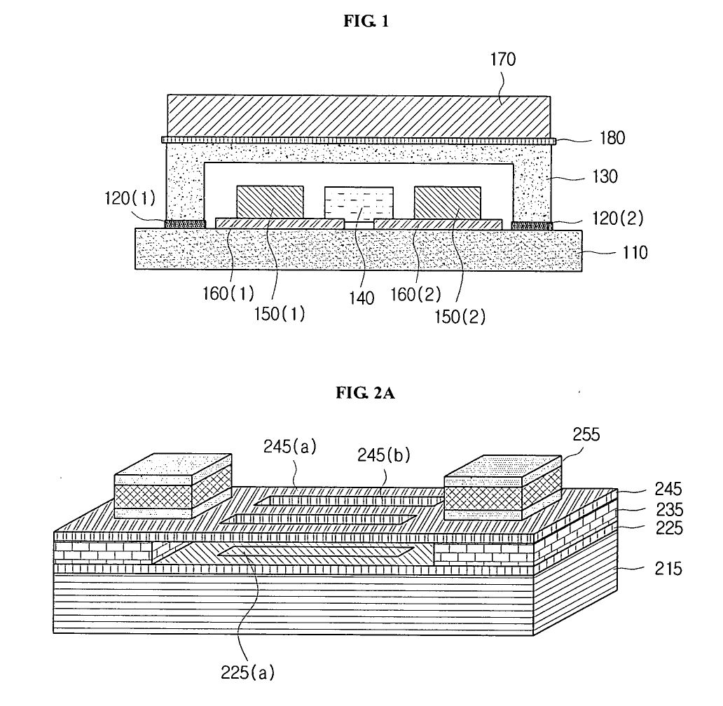

### DETAILED DESCRIPTION

Embodiments of the invention will be described below in more detail with reference to the accompanying drawings. In the description with reference to the accompanying drawings, those components are rendered the same reference number that are the same or are in correspondence regardless of the figure number, and redundant explanations are omitted. Also, the optical modulator, among the various MEMS packages applicable to the invention, will first be described before discussing the disclosed embodiments of the invention.

An optical modulator can be divided mainly into a direct type, which directly controls the on/off state of light, and an indirect type, which uses reflection and diffraction, where the indirect type may further be divided into an electrostatic type and a piezoelectric type. The optical modulator may be applied to the invention regardless of the operational type.

An electrostatic type grating optical modulator as disclosed in U.S. Pat. No. 5,311,360 has light-reflective surfaces and includes a plurality of equally spaced-apart deformable ribbons suspended over the substrate.

First, an insulation layer is deposited on a silicon substrate, followed by a process of depositing a silicon dioxide film and a silicon nitride film. The silicon nitride film is patterned into ribbons, and portions of the silicon dioxide layer are etched so that the ribbons are maintained by the nitride frame on the oxide spacer layer. To modulate light having a single wavelength λ0, the modulator is designed such that the thicknesses of the ribbons and the oxide spacer are λ0/4.

The grating amplitude, of such a modulator limited to the vertical distance d between the reflective surfaces of the ribbons and the reflective surface of the substrate, is controlled by supplying voltage between the ribbons (the reflective surfaces of the ribbons, which act as first electrodes) and the substrate (the conductive film at the bottom portion of the substrate, which acts as the second electrode).

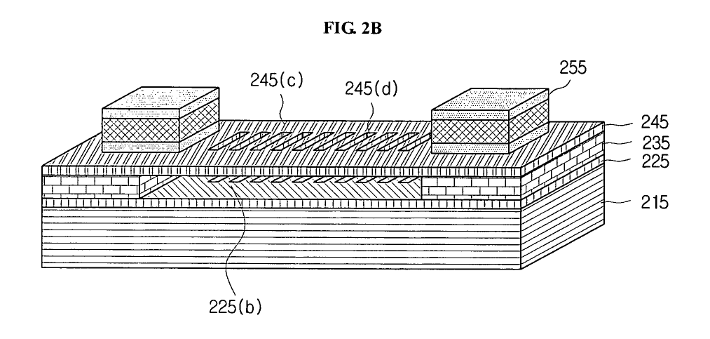

FIG. 2A is a perspective view of a diffraction type optical modulator module using piezoelectric elements, applicable to an embodiment of the invention, and FIG. 2B is a perspective view of another diffraction type optical modulator module using piezoelectric elements, applicable to an embodiment of the invention. In each of FIGS. 2A and 2B, an optical modulator is illustrated which comprises a substrate 215, an insulation layer 225, a sacrificial layer 235, a ribbon structure 245, and piezoelectric elements 255.

The substrate 215 is a generally used semiconductor substrate, while the insulation layer 225 is deposited as an etch stop layer and is formed from a material with a high selectivity to the etchant (the etchant is an etchant gas or an etchant solution) which etches the material used for the sacrificial layer. Here, a reflective layer 225a, 225b may be formed on the insulation layer 225 to reflect incident beams of light.

The sacrificial layer 235 supports the ribbon structure 245 from both sides, such that the ribbon structure may be spaced by a constant gap from the insulation layer 225, and forms a space in the center.

The ribbon structure 245 creates diffraction and interference in the incident light to provide the optical modulation of signals, as described above. The ribbon structure 245 may be composed of a plurality of ribbon shapes according to the electrostatic type, or may comprise a plurality of open holes in the center portion of the ribbons according to the piezoelectric type. The piezoelectric elements 255 control the ribbon structure 245 to move vertically, according to the degree of up/down or left/right contraction or expansion generated by the difference in voltage between the upper and lower electrodes. Here, the reflective layers 225(a), 225(b) are formed in correspondence with the holes 245(b), 245(d) formed in the ribbon structure 245.

For example, in the case where the wavelength of a beam of light is λ, when there is no power supplied or when there is a predetermined amount of power supplied, the gap between an upper reflective layer 245(a), 245(c) formed on the ribbon structure and the insulation layer 225, on which is formed a lower reflective layer 225(a), 225(b), is equal to nλ/2 (wherein n is a natural number). Therefore, in the case of a 0-order diffracted (reflected) beam of light, the overall path length difference between the light reflected by the upper reflective layer 245(a), 245(c) formed on the ribbon structure and the light reflected by the insulation layer 225 is equal to nλ, so that constructive interference occurs and the diffracted light is rendered its maximum luminosity. In the case of +1 or −1 order diffracted light, however, the luminosity of the light is at its minimum value due to destructive interference.

Also, when an appropriate amount of power is supplied to the piezoelectric elements 255, other than the supplied power mentioned above, the gap between the upper reflective layer 245(a), 245(c) formed on the ribbon structure and the insulation layer 225, on which is formed the lower reflective layer 225(a), 225(b), becomes (2n+1)λ/4 (wherein n is a natural number). Therefore, in the case of a 0-order diffracted (reflected) beam of light, the overall path length difference between the light reflected by the upper reflective layer 245(a), 245(c) formed on the ribbon structure and the light reflected by the insulation layer 225 is equal to (2n+1)λ/2, so that destructive interference occurs, and the diffracted light is rendered its minimum luminosity. In the case of +1 or −1 order diffracted light, however, the luminosity of the light is at its maximum value due to constructive interference. As a result of such interference, the optical modulator can load signals on the beams of light by controlling the quantity of the reflected or diffracted light.

While the foregoing describes the cases in which the gap between the ribbon structure 245 and the insulation layer 225, on which is formed the lower reflective layer 225(a), 225(b), is nλ/2 or (2n+1)λ/4, it is obvious that a variety of embodiments may be applied with regards the present invention which are operated with gaps that allow the control of the interference by diffraction and reflection.

The descriptions below will focus on the type of optical modulator illustrated in FIG. 2A described above.

Referring to FIG. 2C, the optical modulator is composed of an m number of micromirrors 100-1, 100-2, . . . , 100-m, each responsible for pixel #1, pixel #2, #2 . . . , pixel #m, respectively. The optical modulator deals with image information with respect to 1-dimensional images of vertical or horizontal scanning lines (Here, it is assumed that a vertical or horizontal scanning line consists of an m number of pixels.), while each micromirror 100-1, 100-2, . . . , 100-m deals with one pixel among the m pixels constituting the vertical or horizontal scanning line. Thus, the light reflected and diffracted by each micromirror is later projected by an optical scanning device as a 2-dimensional image on a screen. For example, in the case of VGA 640*480 resolution, modulation is performed 640 times on one surface of an optical scanning device (not shown) for 480 vertical pixels, to generate 1 frame of display per surface of the optical scanning device. Here, the optical scanning device may be a polygon mirror, a rotating bar, or a galvano mirror, etc.

While the description below of the principle of optical modulation concentrates on pixel #1, the same may obviously apply to other pixels.

In the present embodiment, it is assumed that the number of holes 245(b)-1 formed in the ribbon structure 245 is two. Because of the two holes 245(b)-1, there are three upper reflective layers 245(a)-1 formed on the upper portion of the ribbon structure 245. On the insulation layer 225, two lower reflective layers are formed in correspondence with the two holes 245(b)-1. Also, there is another lower reflective layer formed on the insulation layer 225 in correspondence with the gap between pixel #1 and pixel #2. Thus, there are an equal number of upper reflective layers 245(a)-1 and lower reflective layers per pixel, and as discussed with reference to FIG. 2A, it is possible to control the luminosity of the modulated light using 0-order diffracted light or ±1-order diffracted light.

FIG. 2D is a schematic diagram illustrating an image generated on a screen by means of a diffraction type optical modulator array applicable to an embodiment of the invention.

Illustrated is a display 285-1, 285-2, 285-3, 285-4, . . . , 285-(k-3), 285-(k-2), 285-(k-1), 285-k generated when beams of light reflected and diffracted by an m number of vertically arranged micromirrors 100-1, 100-2, . . . , 100-m are reflected by the optical scanning device and scanned horizontally onto a screen 275. One image frame may be projected with one revolution of the optical scanning device. Here, although the scanning direction is illustrated as being from left to right (the direction of the arrow), it is apparent that images may be scanned in other directions (e.g. in the opposite direction).

The present invention concerns a method of packaging the optical modulator elements described above, and provides a structure for releasing heat generated at each element (the optical modulator element and driver integrated circuits) in which protrusion portions and/or heat conductive material are formed or joined for a direct connection to the elements where heat is generated. In other words, whereas in the simple sealed structure of prior art, heat is not released directly to the exterior so that there is a large amount of heat accumulation, in a structure using direct contact, the heat generated at the elements is directly transferred to the sealing cap so that there is an outstanding amount of heat release. According to the heat generating elements, more than one protrusion portion may be formed, and more than one heat conductive material may be formed. Also, the sealing cap may release the heat generated by each element by means of a separate heat release plate.

The foregoing explanation described figures generally illustrating the optical modulator, and hereinafter the MEMS module package using a sealing cap having heat releasing capability and manufacturing method thereof according to the present invention will be described based on specific embodiments with reference to the accompanying figures. Six embodiments are disclosed in the description, each of them explained in order.

FIG. 2E is a cross-sectional view of a MEMS module package using a sealing cap having heat releasing capability according to a first disclosed embodiment of the invention. Referring to FIG. 2E, a MEMS module package is illustrated which comprises a lower substrate 210, first adhesive 220(1), 220(2), a sealing cap 230, a MEMS element 240, driver IC's 250(1), 250(2), second adhesive 260(1), 260(2), a printed circuit board 270, third adhesive 280, and a protrusion portion (a) formed on the sealing cap 230.

The lower substrate 210 allows the transmission of incident light entering the MEMS element 240 and of reflected and diffracted light emitted from the MEMS element 240. Thus, the lower substrate 210 may be formed from a transparent material, e.g. glass, or a particular hole may be formed where the MEMS element 240 is mounted to allow the transmission of incident light and reflected and diffracted light. The first adhesive 220(1), 220(2), second adhesive 260(1), 260(2), and third adhesive 280 attach the sealing cap 230 to the lower substrate 210, the MEMS element 240 to the driver IC's 250(1), 250(2) and the lower substrate 210, and the printed circuit board 270 to the sealing cap 230, respectively.

The sealing cap 230 has a protrusion portion (referred to herein as a MEMS-element protrusion to distinguish from protrusion portions joining the driver IC's 250(1), 250(2)) that is in physical contact with the MEMS element 240, has one or more grooves 290(a) and 290(b) formed therein for receiving and housing the MEMS element 240 and driver IC's 250(1), 250(2), and is positioned in contact with the lower substrate 210. Here, the material of the sealing cap 230 may include a metal, e.g. Invar, Kovar, silver, or copper, etc.

The second adhesive 260(1), 260(2) may be an anisotropic conductive film (ACF) or anisotropic conductive paste (ACP). The second adhesive 260(1), 260(2) is an adhesive that seals the portions where the sealing cap 230 and the lower substrate 210 are attached to each other, and may be a molded resin such as epoxy resin.

The printed circuit board 270 transfers electric signals for operating the MEMS element 240 to the driver IC's 250(1), 250(2). Here, the printed circuit board 270 may be stacked on the sealing cap 230 or under the lower substrate 210. When the printed circuit board 270 is positioned under the lower substrate 210, a particular hole may be formed in the printed circuit board 270 in the portion where the MEMS element 240 is mounted, so as to allow the transmission of incident light and reflected and diffracted light.

Here, since the protrusion portion (a) formed on the sealing cap 230 is formed to be in physical contact with the MEMS element 240, it is able to transfer heat generated at the MEMS element 240 to the exterior.

Such a MEMS module package is manufactured by the following procedures. That is, the MEMS element 240 is mounted on the lower substrate 210, the driver IC's 250(1), 250(2) which operate the MEMS element 240 are mounted adjacently to the MEMS element 240 on the lower substrate 210, and then the MEMS-element conductive material is formed on the MEMS element 240. Afterwards, the sealing cap, which is placed in contact with the MEMS-element conductive material and which has particular grooves formed therein, is attached onto the lower substrate 210 to house the MEMS element 240 and driver IC's in the grooves 290(a) and 290(b), whereby the manufacture of the MEMS module package using a sealing cap having heat releasing capability is complete.

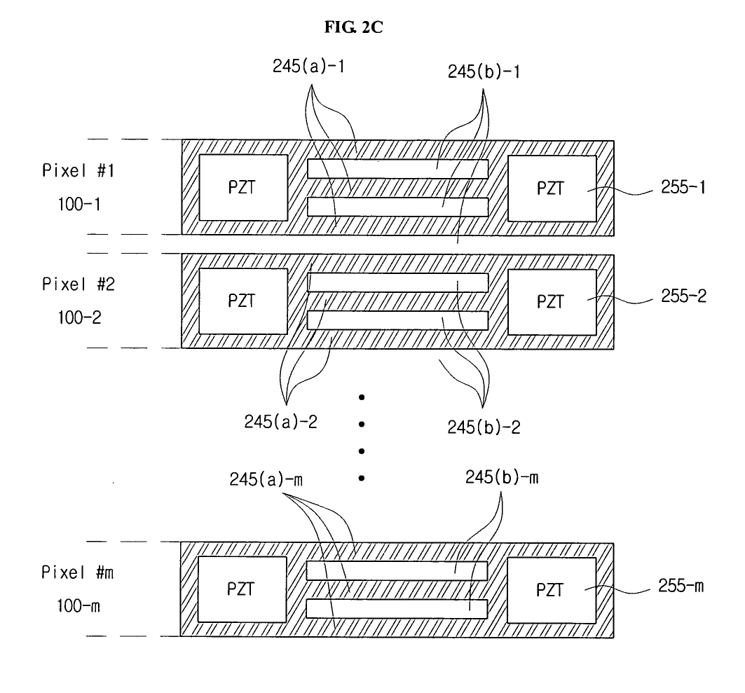

FIG. 3 is a cross-sectional view of a MEMS module package using a sealing cap having heat releasing capability according to a second disclosed embodiment of the invention. Referring to FIG. 3, a MEMS module package is illustrated which comprises a lower substrate 310, first adhesive 320(1), 320(2), a sealing cap 330, a MEMS element 340, driver IC's 350(1), 350(2), second adhesive 360(1), 360(2), a printed circuit board 370, third adhesive 380, and protrusion portions (b, c, d) formed on the sealing cap 330. The description below will be focused on differences from the first disclosed embodiment set forth above.

The protrusion portions (b, c, d) formed on the sealing cap 330 are in physical contact with each of the MEMS element 340 and driver IC's 350(1), 350(2). The protrusion portions (b, c) formed on the sealing cap 330 are herein referred to as driver-IC protrusion portions. The heat generated at the MEMS element 340 and the driver IC's 350(1), 350(2) can thus be transferred to the exterior.

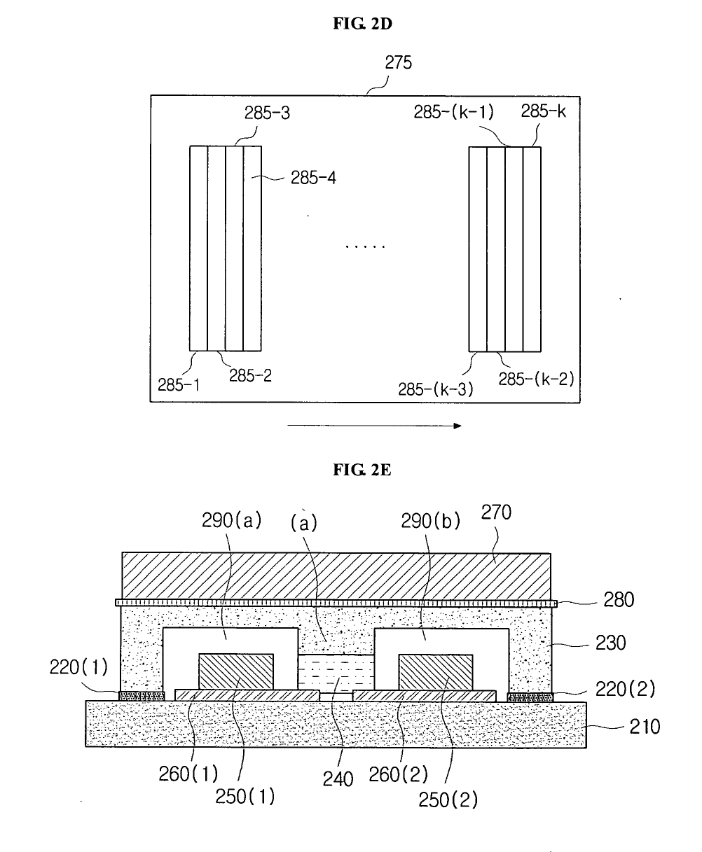

FIG. 4 is a cross-sectional view of a MEMS module package using a sealing cap having heat releasing capability according to a third disclosed embodiment of the invention. Referring to FIG. 4, a MEMS module package is illustrated which comprises a lower substrate 410, first adhesive 420(1), 420(2), a sealing cap 430, a MEMS element 440, driver IC's 450(1), 450(2), second adhesive 460(1), 460(2), a printed circuit board 470, third adhesive 480, and heat conductive material 435. The description below will be focused on differences from the first disclosed embodiment set forth above.

The heat conductive material 435 is in physical contact with the MEMS element 440 and the sealing cap 430. Thus, the heat conductive material 435 for the MEMS element 440 transfers heat generated at the MEMS element 440 to the sealing cap 430, where the sealing cap 430 can release such heat to the exterior. Here, the heat conductive material 435 may be heat conductive paste or a heat conductive pad. Any material having superior heat conduction properties may be used for the heat conductive paste or the heat conductive pad and may be applied to embodiments of the present invention.

Such a MEMS module package is manufactured by the following procedures. That is, the MEMS element 440 is mounted on the lower substrate 410, and the driver IC's 450(1), 450(2) which operate the MEMS element 440 are mounted adjacently to the MEMS element 440 on the lower substrate 410. Then, the heat conductive material 435 for the MEMS element 440 is formed on the MEMS element 440. Afterwards, the sealing cap, which is placed in contact with the MEMS-element conductive material and which has particular grooves 490(a) and 490(b) formed therein, is attached onto the lower substrate 410 to house the MEMS element 440 and driver IC's 450(1), 450(2) in the grooves 490(a) and 490(b), whereby the manufacture of the MEMS module package using a sealing cap having heat releasing capability is complete.

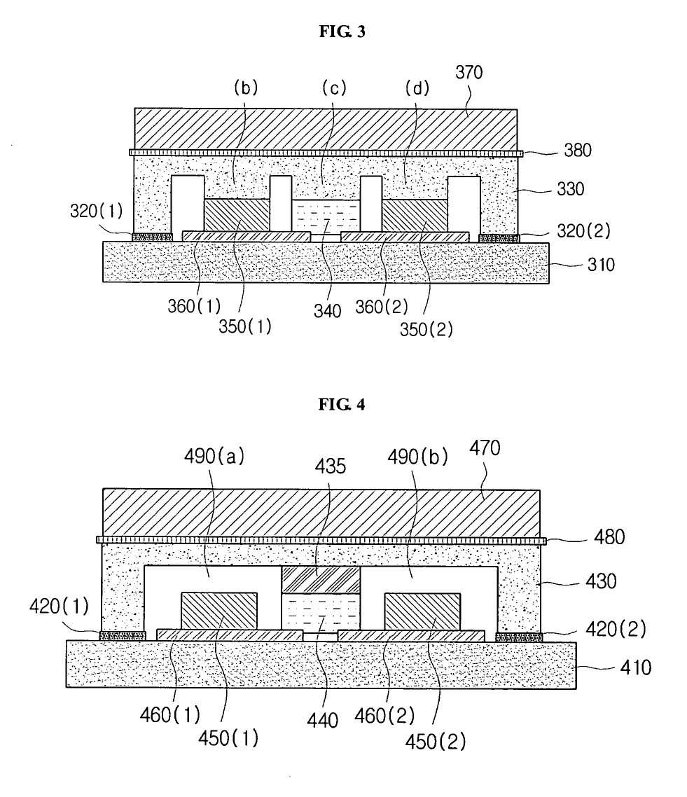

FIG. 5 is a cross-sectional view of a MEMS module package using a sealing cap having heat releasing capability according to a fourth disclosed embodiment of the invention. Referring to FIG. 5, a MEMS module package is illustrated which comprises a lower substrate 510, first adhesive 520(1), 520(2), a sealing cap 530, a MEMS element 540, driver IC's 550(1), 550(2), second adhesive 560(1), 560(2), a printed circuit board 570, third adhesive 580, and heat conductive material 533, 535, 537. The description below will be focused on differences from the third disclosed embodiment set forth above.

The heat conductive material 533, 535, 537 allows the MEMS element 540 and the driver IC's 550(1), 550(2) to be in physical contact with the sealing cap 530. The heat conductive material 535 for the MEMS element 540 and the heat conductive material 533, 537 for the driver IC's 550(1), 550(2) thus transfer heat generated at the MEMS element 540 and driver IC's 550(1), 550(2) to the sealing cap 530, where the sealing cap 530 can release such heat to the exterior.

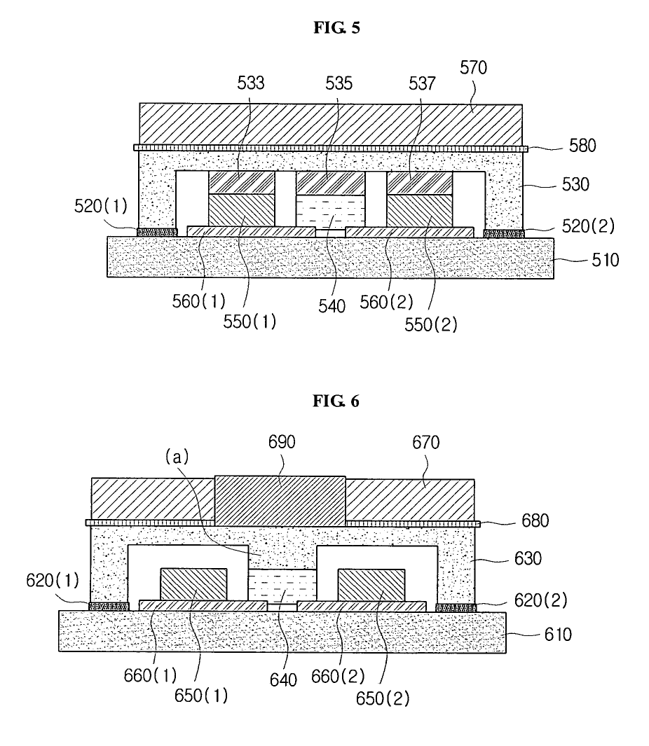

FIG. 6 is a cross-sectional view of a MEMS module package using a sealing cap having heat releasing capability according to a fifth disclosed embodiment of the invention. Referring to FIG. 6, a MEMS module package is illustrated which comprises a lower substrate 610, first adhesive 620(1), 620(2), a sealing cap 630, a MEMS element 640, driver IC's 650(1), 650(2), second adhesive 660(1), 660(2), a printed circuit board 670, third adhesive 680, and a heat release plate 690. The description below will be focused on differences from the first disclosed embodiment set forth above.

The heat release plate 690 is housed in a hole formed in the printed circuit board 670, and is in physical contact with the sealing cap 630. The heat release plate 690 thus releases the heat transferred from the sealing cap 630 to the exterior.

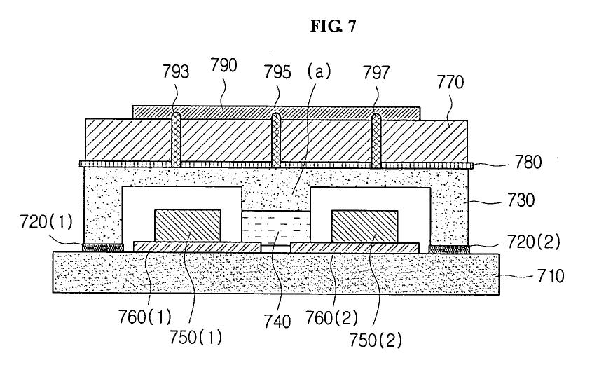

FIG. 7 is a cross-sectional view of a MEMS module package using a sealing cap having heat releasing capability according to a sixth disclosed embodiment of the invention. Referring to FIG. 7, a MEMS module package is illustrated which comprises a lower substrate 710, first adhesive 720(1), 720(2), a sealing cap 730, a MEMS element 740, driver IC's 750(1), 750(2), second adhesive 760(1), 760(2), a printed circuit board 770, third adhesive 780, a heat release plate 790, and heat release paths 793, 795, and 797. The description below will be focused on differences from the fifth disclosed embodiment set forth above.

The heat release plate 790 is positioned on an upper portion of the printed circuit board 770, and is in physical contact with the sealing cap 730. The heat release plate 790 thus releases the heat transferred from the sealing cap 730 to the exterior. The heat release paths 793, 795, 797 receive heat from the sealing cap 730 and transfer the heat to the heat release plate 690. The material of the heat release paths 793, 795, 797 may include a metal, e.g. Invar, Kovar, silver, or copper, etc.

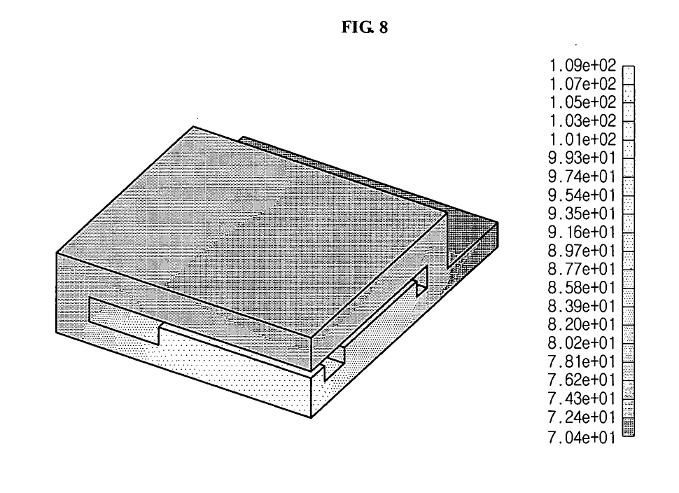

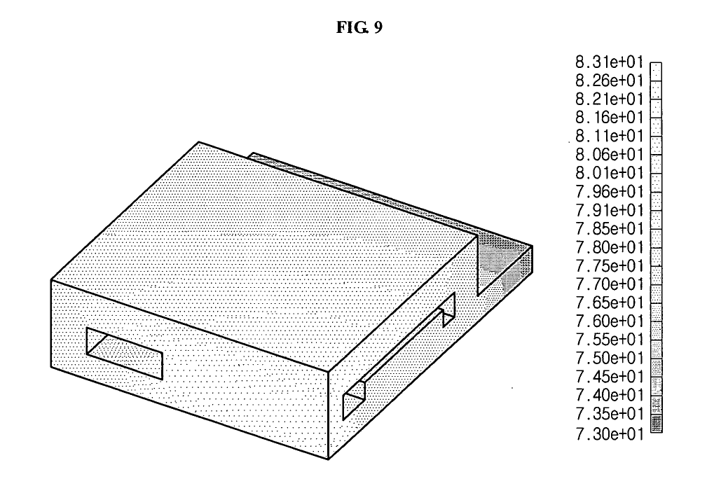

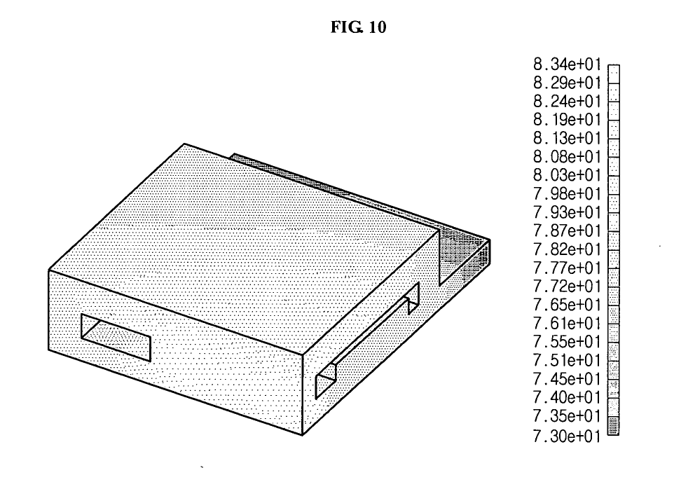

FIGS. 8 to 10 are graphical representations of thermal conduction analysis according to embodiments of the invention. FIG. 8 is a thermal conduction analysis for prior art, while FIG. 9 is a thermal conduction analysis for the first disclosed embodiment and FIG. 10 is a thermal conduction analysis for the third disclosed embodiment.

Referring to FIGS. 9 and 10, it is seen that the amounts of heat have decreased by about 75.7%, and 76.5% respectively compared to the case illustrated in FIG. 8. That is, comparing the relative degrees of temperature, while the temperature of the MEMS module package according to prior art is 111° C., the temperature of the MEMS module package according to the first disclosed embodiment is 82.5° C., and the temperature of the MEMS module package according to the third disclosed embodiment is 83.4° C. The analysis method applied here is finite element analysis.

The present invention is not limited to the foregoing embodiments, and it is to be appreciated that those skilled in the art can change or modify the embodiments without departing from the spirit of the invention.

As set forth above, the MEMS module package using a sealing cap having heat releasing capability and a manufacturing method thereof according to an aspect of the present invention utilize an effective heat releasing structure to release the heat generated in each element.

Also, the MEMS module package using a sealing cap having heat releasing capability and a manufacturing method thereof according to an aspect of the present invention utilize the sealing cap connected to each element to release the heat generated.

Further, in the MEMS module package using a sealing cap having heat releasing capability and a manufacturing method thereof according to an aspect of the present invention, a variety of heat releasing structures are joined to the sealing cap to effectively release the heat generated in the elements.

Also, with the MEMS module package using a sealing cap having heat releasing capability and a manufacturing method thereof according to an aspect of the present invention, thermally conductive material is positioned between the sealing cap and each element, so that the processing of the sealing cap is made convenient and the inner structure of the sealing cap can be adjusted freely as necessary.

In addition, the MEMS module package using a sealing cap having heat releasing capability and a manufacturing method thereof according to an aspect of the present invention allow the heat generated in each element to be released through the sealing cap and a heat release plate.

While the invention has been described with reference to the disclosed embodiments, it is to be appreciated that those skilled in the art can change or modify the embodiments without departing from the scope and spirit of the invention or its equivalents as stated below in the claims.

The embodiments of the invention in which an exclusive property or privilege is claimed are defined as follows:

1. A MEMS module package using a sealing cap having heat releasing capability, the MEMS module package comprising:
a substrate;
a MEMS element mounted on the substrate;
a driver integrated circuit mounted on the substrate adjacently to the MEMS element and configured to operate the MEMS element; and
a sealing cap, positioned in contact with the substrate, having a MEMS element protrusion portion in physical contact with the MEMS element, said MEMS element protrusion portion is configured for housing the MEMS element.

2. The MEMS module package of claim 1, wherein the MEMS element protrusion portion is contoured for housing the MEMS element.

3. The MEMS module package of claim 2, wherein the MEMS element protrusion portion has at least one groove for housing the MEMS element.

4. The MEMS module package of claim 1, wherein the sealing cap further comprises a driver-IC protrusion portion positioned in physical contact with the driver integrated circuit.

5. The MEMS module package of claim 1, wherein the substrate is formed from a material that is substantially transparent in the area of the MEMS element.

6. The MEMS module package of claim 1, further comprising a printed circuit board positioned on the sealing cap and configured to transfer an electric signal to the driver integrated circuit.

7. The MEMS module package of claim 1, further comprising a printed circuit board positioned adjacent the substrate and relative to the substrate opposite to the location of the MEMS element, said printed circuit board configured to transfer an electric signal to the driver integrated circuit.

8. The MEMS module package of claim 4, further comprising a heat release plate housed in a hole formed in the printed circuit board and configured to allow heat conduction from the sealing cap.

9. The MEMS module package of claim 4, further comprising a heat release plate positioned on the printed circuit board and configured to allow heat conduction from the sealing cap,
wherein the heat release plate and the sealing cap are connected by at least one heat path formed in the printed circuit board.

10. The MEMS module package of claim 1, wherein the MEMS element is an optical modulator configured to reflect and diffract modulated light in correspondence to an operation signal received from the driver integrated circuit.

11. A MEMS module package using a sealing cap having heat releasing capability, the MEMS module package comprising:
a substrate;
a MEMS element mounted on the substrate;
a driver integrated circuit mounted on the substrate adjacently to the MEMS element and configured to operate the MEMS element;
a sealing cap, positioned in contact with the substrate; and
a MEMS element heat conductive material disposed between the sealing cap and the MEMS element and in physical contact with the sealing cap and the MEMS element.

12. The MEMS module package of claim 9, further comprising a driver-IC heat conductive material positioned in physical contact with the driver integrated circuit and the sealing cap.

13. The MEMS module package of claim 10, wherein the MEMS element heat conductive material or the driver-IC heat conductive material comprises heat conductive paste or a heat conductive pad.

14. The MEMS module package of claim 9, wherein the substrate is formed from a transparent material in at least the location of the MEMS element.

15. The MEMS module package of claim 9, further comprising a printed circuit board positioned on the sealing cap and configured to transfer an electric signal to the driver integrated circuit.

16. The MEMS module package of claim 9, further comprising a printed circuit board positioned adjacent the substrate at a location opposite to the location of the MEMS's element relative to the substrate, the printed circuit board configured to transfer an electric signal to the driver integrated circuit.

17. The MEMS module package of claim 13, further comprising a heat release plate housed in a hole formed in the printed circuit board and configured to allow heat conduction from the sealing cap.

18. The MEMS module package of claim 13, further comprising a heat release plate positioned on the printed circuit board and configured to allow heat conduction from the sealing cap,
wherein the heat release plate and the sealing cap are connected by at least one heat path formed in the printed circuit board.

19. The MEMS module package of claim 9, wherein the MEMS element is an optical modulator configured to reflect and diffract modulated light in correspondence to an operation signal received from the driver integrated circuit.
